(19) United States
(12) Patent Application Publication
(10) Pub. No.: US 2025/0125263 A1
(43) Pub. Date: Apr. 17, 2025

(54) SEMICONDUCTOR DEVICE INCLUDING TRANSISTOR AND METHOD FOR FABRICATING THE SAME

(71) Applicant: SK hynix Inc., Gyeonggi-do (KR)

(72) Inventors: Seung Ju LEE, Gyeonggi-do (KR); Do Young JANG, Gyeonggi-do (KR)

(21) Appl. No.: 18/600,775

(22) Filed: Mar. 11, 2024

(30) Foreign Application Priority Data
Oct. 12, 2023 (KR) 10-2023-0135933

(51) Int. Cl. H01L 23/528; H01L 21/768; H01L 23/532; H01L 29/06

(52) U.S. Cl. CPC H01L 23/5283; H01L 21/7684; H01L 23/53209; H01L 23/5329; H10D 62/102

(57) ABSTRACT

A semiconductor device and a method for fabricating the same are provided. The semiconductor device includes a semiconductor pattern; an impurity region disposed at a side of the semiconductor pattern and having a lower surface that forms a flat surface with a lower surface of the semiconductor pattern; a gate structure disposed under the semiconductor pattern; and a contact plug disposed over the impurity region and electrically connected to the impurity region.

### CROSS-REFERENCE TO RELATED APPLICATION

This application claims priority under 35 U.S.C. § 119 to Korean Patent Application No. 10-2023-0135933 filed on Oct. 12, 2023, which is incorporated herein by reference in its entirety.

### BACKGROUND

### 1. Technical Field

Embodiments of the present disclosure relate to a semiconductor technology, and more particularly, to a semiconductor device including a transistor, and a method for fabricating the same.

### 2. Related Art

With the development of the electronics industry, electronic products are gradually becoming smaller, more high-performance, and more highly integrated. To meet these demands, there is a need to develop technology that can maintain and/or improve the characteristics of unit elements that make up electronic products, such as transistors, while reducing the area occupied by them.

### SUMMARY

In an embodiment of the present disclosure, a semiconductor device may include a semiconductor pattern; an impurity region disposed at a side of the semiconductor pattern and having a lower surface that forms a flat surface with a lower surface of the semiconductor pattern; a gate structure disposed under the semiconductor pattern; and a contact plug disposed over the impurity region and electrically connected to the impurity region.

In an embodiment of the present disclosure, a semiconductor device is provided which includes a semiconductor pattern, and an impurity region disposed at a side of the semiconductor pattern, wherein the impurity region has a bottom surface that forms a flat surface with a bottom surface of the semiconductor pattern. The semiconductor device further includes a gate structure disposed under the semiconductor pattern. The gate structure may fully overlap with the semiconductor pattern in a lateral direction. The semiconductor device may further include a contact plug disposed over the impurity region. The contact plug may be electrically connected to the impurity region. The semiconductor device may further include an insulating layer disposed under the impurity region and may cover the impurity region.

In an embodiment of the present disclosure, a method for fabricating a semiconductor device, may include forming a gate structure or sacrificial gate pattern on a semiconductor substrate; forming an impurity region by doping impurities into the semiconductor substrate exposed by the gate structure or the sacrificial gate pattern; after flipping the semiconductor substrate in which the impurity region is formed upside down, performing a planarization process to expose the impurity region; and forming a contact plug over the planarized impurity region.

### BRIEF DESCRIPTION OF THE DRAWINGS

FIGS. 1A to 1F are cross-sectional views illustrating a semiconductor device and a method for fabricating the same, according to an embodiment of the present disclosure.

FIG. 2 is a cross-sectional view illustrating a semiconductor device according to another embodiment of the present disclosure.

FIG. 3 is a cross-sectional view illustrating a semiconductor device according to another embodiment of the present disclosure.

FIGS. 4A to 4D are cross-sectional views illustrating a semiconductor device and a method for fabricating the same, according to another embodiment of the present disclosure.

FIGS. 5A to 5D are cross-sectional views illustrating a semiconductor device and a method for fabricating the same, according to another embodiment of the present disclosure.

FIGS. 6A to 6E are cross-sectional views illustrating a semiconductor device and a method for fabricating the same, according to another embodiment of the present disclosure.

### DETAILED DESCRIPTION

Hereinafter, various embodiments of the present disclosure will be described in detail with reference to the accompanying drawings.

The drawings are not necessarily drawn to scale. In some instances, proportions of at least some structures in the drawings may have been exaggerated to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

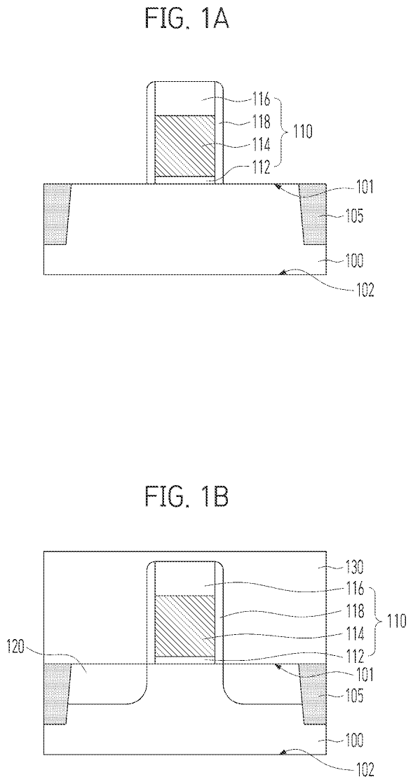

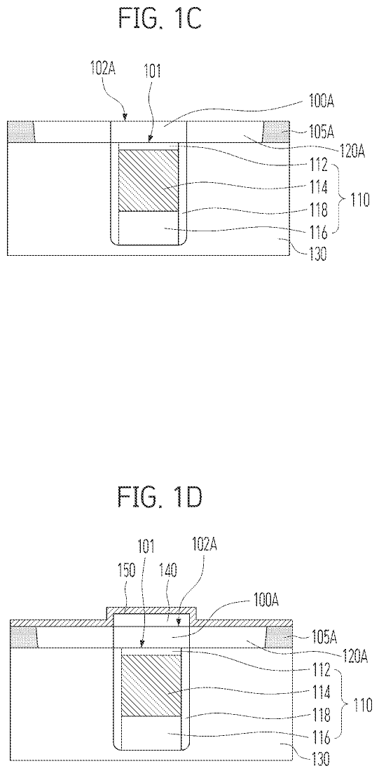

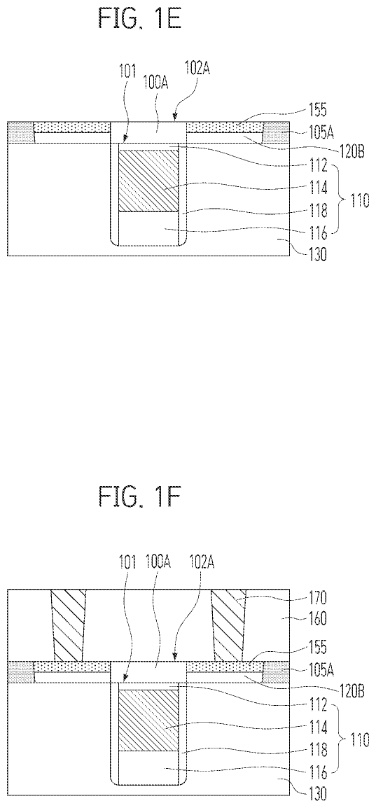

FIGS. 1A to 1F are cross-sectional views illustrating a semiconductor device and a method for fabricating the same, according to an embodiment of the present disclosure.

Hereinafter, the fabricating method will first be described.

Referring to FIG. 1A, a semiconductor substrate 100 may be provided. The semiconductor substrate 100 may include a semiconductor material such as silicon or silicon germanium. The semiconductor substrate 100 may include a first surface 101, an initial second surface 102 opposite to the first surface 101, and a side surface connecting the first surface 101 and the second surface. In this process, the semiconductor substrate 100 may be disposed so that the first surface 101 is positioned over the initial second surface 102.

Subsequently, an isolation layer 105 may be formed to define an active region in the semiconductor substrate 100. The isolation layer 105 may be formed by etching the semiconductor substrate 100 to a predetermined depth to form a trench, depositing an insulating material having a thickness that sufficiently fills the trench, and performing a planarization process, such as CMP (Chemical Mechanical Polishing), to expose the upper surface of the semiconductor substrate 100. The etching for forming the trench may be performed using a mask pattern (not shown) covering the active region of the semiconductor substrate 100 as an etch barrier. The isolation layer 105 may include at least one of various insulating materials, such as silicon oxide, silicon nitride, silicon oxynitride, or a combination thereof.

Subsequently, a gate structure 110 may be formed over the semiconductor substrate 100. The gate structure 110 may include a gate insulating layer 112, a gate electrode 114, and a gate hard mask 116 that are sequentially stacked over the semiconductor substrate 100. The gate structure 110 may also include a gate spacer 118 formed over the sidewall of the gate structure 110. The gate insulating layer 112 may include at least one of various insulating materials, such as silicon oxide or a high dielectric constant material having a higher dielectric constant than that of silicon oxide. The gate electrode 116 may include at least one of various conductive materials, for example, a metal such as lanthanum (La), tantalum (Ta), titanium (Ti), niobium (Nb), aluminum (Al), tungsten (W), ruthenium (Ru), copper (Cu), or molybdenum (Mo), a metal nitride containing at least one of these metals, a metal oxide containing at least one of these metals, or an alloy containing two or more of these metals. The gate electrode 116 may have a single-layer structure or a multi-layer structure. Each of the gate hard mask 116 and the gate spacer 118 may include at least one of various insulating materials, such as silicon oxide, silicon nitride, or silicon oxynitride, and may have a single-layer structure or a multi-layer structure. The gate structure 110 may be formed, for example, by depositing an insulating material for forming the gate insulating layer 112, a conductive material for forming the gate electrode 114, and an insulating material for forming the gate hard mask 116, over the semiconductor substrate 100, and then selectively etching the deposited materials to form a stacked structure of the gate insulating layer 112, the gate electrode 114, and the gate hard mask 116, and finally forming the gate spacer 118 over the sidewall of the stacked structure. The gate structure 110 is not limited to the configuration illustrated, and as long as the gate structure 110 includes a gate electrode which is separated from the semiconductor substrate by a gate insulating layer, the shape, the layer structure, and the forming process of the gate structure 110 may be modified variously. For example, as shown in FIG. 3, another type of gate structure may be formed by a replacement metal gate (RMG) process.

Referring to FIG. 1B, an initial impurity region 120 may be formed by doping impurities, for example via ion implantation, into the semiconductor substrate 100 that is exposed by the gate structure 110. A depth of the initial impurity region 120 may be smaller than a depth of the isolation layer 105. The lower surface (also referred to as a bottom surface) of the initial impurity region 120 may be located above a lower surface (also referred to as a bottom surface) of the isolation layer 105. After forming the initial impurity region 120, a heat treatment process may be performed for activating the impurities, such as, for example, a rapid thermal annealing (RTA) process.

Subsequently, a first interlayer insulating layer 130 covering the gate structure 110 may be formed over the semiconductor substrate 100. The first interlayer insulating layer 130 may include at least one of various insulating materials, such as silicon oxide, silicon nitride, or silicon oxynitride, and may have a single-layer structure or a multi-layer structure.

Referring to FIG. 1C, in a state in which the process result of FIG. 1B is flipped upside down so that the initial second surface 102 of the semiconductor substrate 100 is positioned over the first surface 101, a planarization process, such as CMP, may be performed to remove a portion from the initial second surface 102 of the semiconductor substrate 100. The planarization process may be performed to expose the initial impurity region 120, and thus, a portion of the initial impurity region 120 and a portion of the isolation layer 105 may be removed.

The planarized semiconductor substrate 100 will hereinafter be referred to as a semiconductor pattern 100A, the planarized initial impurity region 120 will hereinafter be referred to as an impurity region 120A, and the planarized isolation layer 105 will hereinafter be referred to as an isolation pattern 105A. The semiconductor pattern 100A may include the first surface 101 and a second surface 102A that is located over the first surface 101. The second surface 102A may be positioned under the initial second surface 102. The impurity region 120A may include a lower surface forming a flat surface with the first surface 101 and an upper surface forming a flat surface with the second surface 102A. The isolation pattern 105A may include a lower surface forming a flat surface with the first surface 101 and an upper surface forming a flat surface with the second surface 102A. That is, the semiconductor pattern 100A, the impurity region 120A, and the isolation pattern 105A may be located at the same level in the vertical direction, and may have flat upper surfaces and flat lower surfaces. The gate structure 110 may be disposed under the semiconductor pattern 100A to fully overlap with the semiconductor pattern 100A in a lateral direction (left to right direction), meaning that the sidewall of the gate structure 110 is aligned with the sidewall of the semiconductor pattern 100A in the lateral direction. The lateral direction refers to the horizontal direction which is a direction parallel to the plane defined by a top surface of the semiconductor substrate 100. However, the embodiments of the present disclosure are not limited to this, and depending on the shape of the impurity region 120A, the sidewall of the semiconductor pattern 100A and the sidewall of the gate structure 110 may not be exactly aligned with each other. The first interlayer insulating layer 130 may be formed to cover the gate structure 110, thereby covering the impurity region 120A and the isolation pattern 105A under the impurity region 120A and the isolation pattern 105A. That is, the first interlayer insulating layer 130 may contact the lower surface of the impurity region 120A and the lower surface of the isolation pattern 105A.

As a result of this process, a transistor including the gate structure 110, the semiconductor pattern 100A, and the impurity region 120A may be formed. The gate structure 110 may correspond to a gate of the transistor, the semiconductor pattern 100A may correspond to a channel of the transistor, and the impurity region 120A may correspond to a source or a drain of the transistor.

Additionally, a silicidation process may be performed to reduce the resistance of the impurity region 120A. This will be described with reference to FIGS. 1D and 1E.

Referring to FIG. 1D, a sacrificial insulating pattern 140 covering the semiconductor pattern 100A may be formed over the process result of FIG. 1C. The sacrificial insulating pattern 140 may include at least one of various insulating materials, such as silicon oxide, silicon nitride, or silicon oxynitride.

Subsequently, a metal layer 150 may be formed over the sacrificial insulating pattern 140, the impurity region 120A, and the isolation pattern 105A along the profile of the sacrificial insulating pattern 140, the impurity region 120A, and the isolation pattern 105A. The metal layer 150 may be formed by deposition, and may include at least one of various metals such as cobalt (Co), nickel (Ni), or titanium (Ti).

Referring to FIG. 1E, a heat treatment process may be performed on the process result of FIG. 1D to react the metal of the metal layer 150 with silicon of the impurity region 120A. By the reaction of the metal and the silicon, a metal silicide layer 155 may be formed. In this process, the upper portion of the impurity region 120A may be transformed into the metal silicide layer 155, and a remaining portion of the impurity region 120A is denoted hereinafter as impurity region 120B. As a result, the metal silicide layer 155 may be located over the impurity region 120B, and the sidewall of the impurity region 120B may be aligned with the sidewall of the metal silicide layer 155. The upper surface of the impurity region 120B may be located below the second surface 102A of the semiconductor pattern 100A, and the upper surface (i.e., the top surface) of the metal silicide layer 155 may be at the same level with the second surface 102A of the semiconductor pattern 100A. The upper surface (i.e., the top surface) of the metal silicide layer 155 may form a flat surface with the second surface 102A of the semiconductor pattern 100A. However, the embodiment of the present disclosure are not limited to this, and depending on the shape of the sacrificial insulating pattern 140, the sidewall of the impurity region 120B may not be aligned with the sidewall of the metal silicide layer 155.

Subsequently, the unreacted portion of the metal layer 150 and the sacrificial insulating pattern 140 may be removed.

The processes of FIGS. 1D and 1E described above may be optional, and thus, may be omitted.

Referring to FIG. 1F, a second interlayer insulating layer 160 and a contact plug 170 that penetrates the second interlayer insulating layer 160 to be connected to the metal silicide layer 155 may be formed over the process result of FIG. 1E.

The second interlayer insulating layer 160 may include at least one of various insulating materials, such as silicon oxide, silicon nitride, or silicon oxynitride, and may have a single-layer structure or a multi-layer structure. The contact plug 170 may include at least one of various conductive materials, for example, a metal such as lanthanum (La), tantalum (Ta), titanium (Ti), niobium (Nb), aluminum (Al), tungsten (W), ruthenium (Ru), copper (Cu), or molybdenum (Mo), a metal nitride containing at least one of these metals, a metal oxide containing at least one of these metals, or an alloy containing two or more of these metals, and may have a single-layer structure or a multi-layer structure. The second interlayer insulating layer 160 and the contact plug 170 may be formed by depositing an insulating material for forming the second interlayer insulating layer 160 over the process result of FIG. 1E, selectively etching the insulating material to form a hole exposing the metal silicide layer 155, and filling the hole with a conductive material.

The contact plug 170 may be in direct contact with the metal silicide layer 155, and may be electrically connected to the impurity region 120B through the metal silicide layer 155.

When the processes of FIGS. 1D and 1E are omitted, the process of forming the second interlayer insulating layer 160 and the contact plug 170 of FIG. 1F may be performed after the process of FIG. 1C. In this case, the contact plug 170 may directly contact the impurity region 120A to be electrically connected to the impurity region 120A.

The semiconductor device of the present embodiment may be fabricated through the processes described above.

Referring again to FIG. 1F, the semiconductor device of the present embodiment may include the semiconductor pattern 100A, a stacked structure including a structure in which the impurity region 120B and the metal silicide layer 155 are stacked and disposed at a side of the semiconductor pattern 100A, the isolation pattern 105A disposed at a side of the stacked structure, the gate structure 110 disposed under the semiconductor pattern 100A, the first interlayer insulating layer 130 disposed under the impurity region 120B and the isolation pattern 105A to cover them, the second interlayer insulating layer 160 disposed over the semiconductor pattern 100A, the metal silicide layer 155, and the isolation pattern 105A to cover them, and the contact plug 170 that penetrates through the second interlayer insulating layer 150 and contacts the metal silicide layer 155. The contact plug 170 may be electrically connected to the impurity region 120B through the metal silicide layer 155.

Here, the semiconductor pattern 100A, the stacked structure of the impurity region 120B and the metal silicide layer 155, and the isolation pattern 105A may be located at the same level in the vertical direction, and thus, may have the upper surfaces planarized with each other and the lower surfaces planarized with each other. When the metal silicide layer 155 is omitted, the semiconductor pattern 100A, the impurity region (see 120A in FIG. 1C), and the isolation pattern 105A may be located at the same level in the vertical direction, and thus, may have the upper surfaces planarized with each other and the lower surfaces planarized with each other.

According to the semiconductor device and its fabricating method described above, the following effects may be obtained.

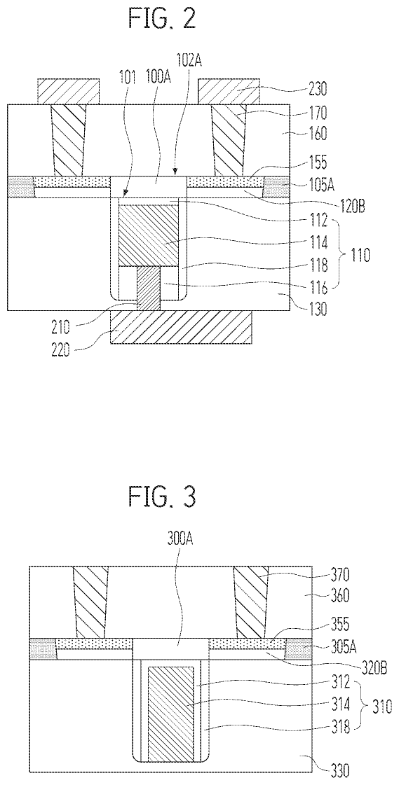

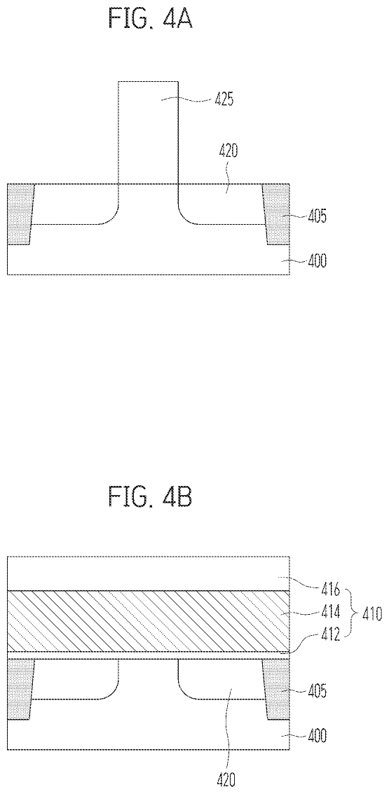

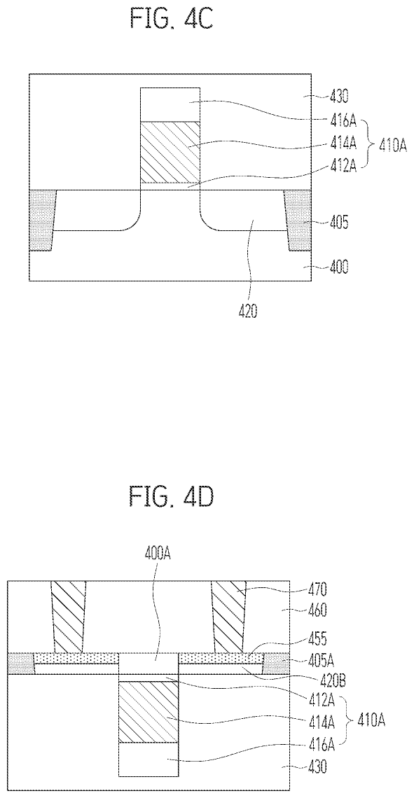

First, because the gate structure 110 and the contact plug 170 are located at different levels in the vertical direction and are spatially separated from each other by the semiconductor pattern 100A with a fully depleted state, there may be several advantages compared to the prior art in which a gate structure is disposed between two contact plugs. For example, the space between the two contact plugs 170 may be reduced while ensuring sufficient spaces for forming the gate structure 110 and for forming the contact plug 170, and accordingly, the scaling of the semiconductor device may be advantageous. In addition, various defects that may occur when the contact plug and the gate structure are adjacent to each other, such as an electrical short defect between the contact plug and the gate structure, may be prevented. That is, an electrical short between the contact plug 170 and the gate structure 110 may not occur. In addition, since there is no need to consider the occurrence of an electrical short between the contact plug 170 and the gate structure 110, the gate spacer 118 of the gate structure 110 may be omitted, thereby simplifying the processes. In addition, since the parasitic capacitance between the contact plug 170 and the gate structure 110 is reduced, the performance of the transistor may be improved. In addition, as will be described later, routing of conductive lines may become more advantageous (see FIG. 2), the RMG process, which requires securing a sufficient line width of the gate, may become easier (see FIG. 3), and the degree of freedom in the process sequence may increase, thereby further improving the performance of the transistor (see FIGS. 4A to 6E).

In addition, since the lower surface of the impurity region 120B is covered with the first interlayer insulating layer 130, the impurity region 120B may have a fully depleted state. Therefore, leakage current through the impurity region 120B may be prevented or reduced.

FIG. 2 is a cross-sectional view illustrating a semiconductor device according to another embodiment of the present disclosure.

Referring now to FIG. 2, the semiconductor device of the present embodiment may further include a gate contact 210, a first conductive line 220, and a second conductive line 230, in addition to the components of the semiconductor device of FIG. 1F.

The gate contact 210 may be electrically connected to the gate electrode 114 by penetrating the first interlayer insulating layer 130 and the gate hard mask 116.

The first conductive line 220 may be disposed under the first interlayer insulating layer 130 and connected to the gate contact 210.

The second conductive line 230 may be disposed over the second interlayer insulating layer 160 and connected to the contact plug 170.

The gate contact 210 and the first conductive line 220 may be formed after the gate structure 110 and the first interlayer insulating layer 130 are formed. For example, the process of forming the gate contact 210 and the first conductive line 220 may be performed after the process of FIG. 1B, or may be performed after flipping the process result of FIG. 1F upside down.

The second conductive line 230 may be formed after the contact plug 170 is formed. For example, the second conductive line 230 may be performed after the process of FIG. 1F.

In the present embodiment, the first conductive line 220 electrically connected to the gate structure 110 and the second conductive line 230 electrically connected to the contact plug 170 may be located at different levels in the vertical direction. Accordingly, the space for forming the first conductive line 220 and the space for forming the second conductive line 230 may be increased, so that routing of the first conductive line 220 and the second conductive line 230 may be facilitated.

FIG. 3 is a cross-sectional view illustrating a semiconductor device according to another embodiment of the present disclosure.

Referring to FIG. 3, the semiconductor device of the present embodiment may include: a semiconductor pattern 300A, a stacked structure including a structure in which an impurity region 320B and a metal silicide layer 355 are stacked and disposed at a side of the semiconductor pattern 300A, an isolation pattern 305A disposed at a side of the stacked structure, a gate structure 310 disposed under the semiconductor pattern 300A, a first interlayer insulating layer 330 disposed under the impurity region 320B and the isolation pattern 305A to cover them, a second interlayer insulating layer 360 disposed over the semiconductor pattern 300A, the metal silicide layer 355, and the isolation pattern 305A to cover them, and a contact plug 370 that penetrates through the second interlayer insulating layer 360 and contacts the metal silicide layer 355. The contact plug 370 may be electrically connected to the impurity region 320B through the metal silicide layer 355.

Here, the gate structure 310 may be different from the gate structure (see 110 in FIG. 1F) of the above-described embodiment. The gate structure 310 may include a gate insulating layer 312, a gate electrode 314, and a gate spacer 318. The gate insulating layer 312 may be formed along the inner wall of the space defined by the gate spacer 318, that is, along the inner wall of the gate spacer 318 and the lower surface of the semiconductor pattern 300A. The gate electrode 314 may be formed to fill the remainder of the space defined by the gate spacer 318, and accordingly, may have a sidewall and an upper surface surrounded by the gate insulating layer 312.

A process for forming the gate structure 310 may include, forming a sacrificial gate pattern over a semiconductor substrate, forming a gate spacer 318 over a sidewall of the sacrificial gate pattern, providing a space by selectively removing the sacrificial gate pattern, forming a gate insulating layer 312 along the inner wall of the provided space, filling the remaining space with a conductive material to form the gate electrode 314, and flipping the semiconductor substrate upside down to provide the gate structure 310 as shown in FIG. 3.

Because the sacrificial gate pattern is replaced with the gate electrode 314, this process may be referred to as an RMG process. In this RMG process, the gate structure 310 may be required to have a large line width because a space for filling a conductive material is needed. In the present embodiment, having the contact plug 370 located at a different level from the gate structure 310 in the vertical direction, is advantageous because it is easier to increase the line width of the gate structure 310.

FIGS. 4A to 4D are cross-sectional views illustrating a semiconductor device and a method for fabricating the same, according to another embodiment of the present disclosure.

Referring to FIG. 4A, an isolation layer 405 may be formed to define an active region in the semiconductor substrate 400.

Subsequently, a sacrificial gate pattern 425 may be formed over the semiconductor substrate 400. The sacrificial gate pattern 425 may expose a region where an impurity region is to be formed. The sacrificial gate pattern 425 may include polysilicon. However, the embodiments of the present disclosure are not limited thereto, and the sacrificial gate pattern 425 may include at least one of various materials that are easy to remove.

Subsequently, an initial impurity region 420 may be formed by doping impurities into the semiconductor substrate 400 that is exposed by the sacrificial gate pattern 425. After forming the initial impurity region 420, a heat treatment process to activate the impurities may be performed.

Referring to FIG. 4B, after removing the sacrificial gate pattern 425, an initial gate structure 410 may be formed over the semiconductor substrate 400 in which the initial impurity region 420 is formed. The initial gate structure 410 may include an initial gate insulating layer 412, an initial gate electrode 414, and an initial gate hard mask 416.

Referring to FIG. 4C, the initial gate structure 410 may be selectively etched to form a gate structure 410A in which a gate insulating layer 412A, a gate electrode 414A, and a gate hard mask 416A are stacked. The gate structure 410A may be formed to cover a region that overlaps with a region covered by the sacrificial gate pattern 425. Thus, the initial impurity region 420 may be positioned in the semiconductor substrate 400 at both sides of the gate structure 410A.

Subsequently, a first interlayer insulating layer 430 may be formed over the semiconductor substrate 400 for covering the gate structure 410A.

Referring to FIG. 4D, after flipping the process result of FIG. 4C upside down, substantially the same processes as the processes described in FIGS. 1C to 1F, that is, the planarization process, the silicidation process, and the forming process of the contact plug, may be performed. Thus, a semiconductor pattern 400A, an impurity region 420B, a metal silicide layer 455, an isolation pattern 405A, a second interlayer insulating layer 460, and a contact plug 470 may be formed.

According to the present embodiment, after forming the initial impurity region 420 and the heat treatment process, the gate structure 410A may be formed. Accordingly, deterioration of the gate structure 410A due to the heat treatment process may be prevented.

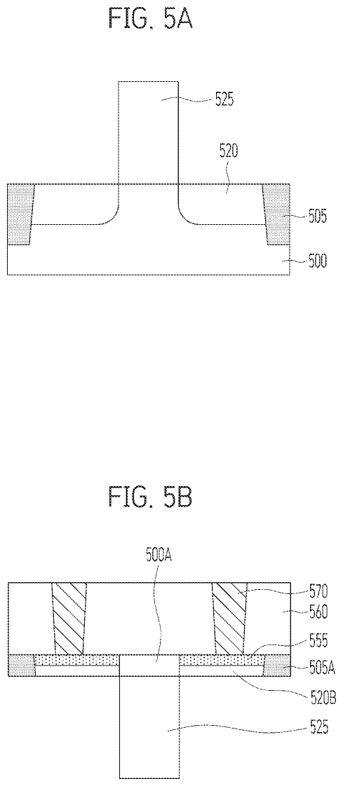

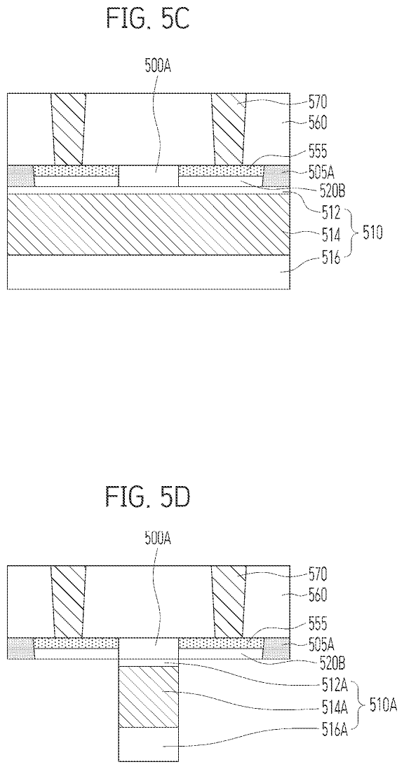

FIGS. 5A to 5D are cross-sectional views illustrating a semiconductor device and a method for fabricating the same, according to another embodiment of the present disclosure.

Referring to FIG. 5A, an isolation layer 505 may be formed to define an active region in the semiconductor substrate 500.

Subsequently, after forming a sacrificial gate pattern 525 over the semiconductor substrate 500, an initial impurity region 520 may be formed by doping impurities into the semiconductor substrate 500 exposed by the sacrificial gate pattern 525. Subsequently, a heat treatment process to activate the impurities in the initial impurity region 520 may be performed.

Referring to FIG. 5B, after flipping the process result of FIG. 5A upside down, substantially the same processes as the processes described in FIGS. 1C to 1F, that is, the planarization process, the silicidation process, and the forming process of the contact plug, may be performed. Thus, a semiconductor pattern 500A, an impurity region 520B, a metal silicide layer 555, an isolation pattern 505A, a second interlayer insulating layer 560, and a contact plug 570 may be formed.

Referring to FIG. 5C, after removing the sacrificial gate pattern 525, an initial gate structure 510 may be formed under the semiconductor pattern 500A, the impurity region 520B, and the isolation pattern 505A. The initial gate structure 510 may include an initial gate insulating layer 512, an initial gate electrode 514, and an initial gate hard mask 516 that are stacked.

Referring to FIG. 5D, the initial gate structure 510 may be selectively etched to form a gate structure 510A in which a gate insulating layer 512A, a gate electrode 514A, and a gate hard mask 516A are stacked.

The processes of FIGS. 5C and 5D may be performed after flipping the process result of FIG. 5B upside down.

Subsequently, although not shown, a process of forming a first interlayer insulating layer covering the gate structure 510A may be further performed. The first interlayer insulating layer forming process may also be performed after flipping the process result of FIG. 5B upside down.

According to the present embodiment, after the forming process of the initial impurity region 520, the heat treatment process for activating the impurities and/or for forming the metal silicide layer 555, and also the forming process of the contact plug 570, the gate structure 510A may be performed. Accordingly, deterioration of the gate structure 510A due to the heat treatment process or the forming process of the contact plug 570 may be prevented.

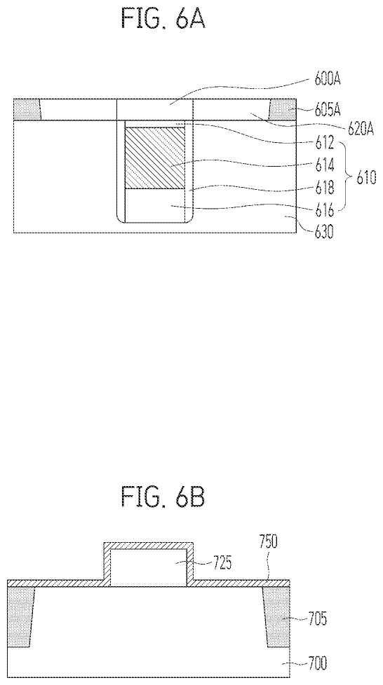

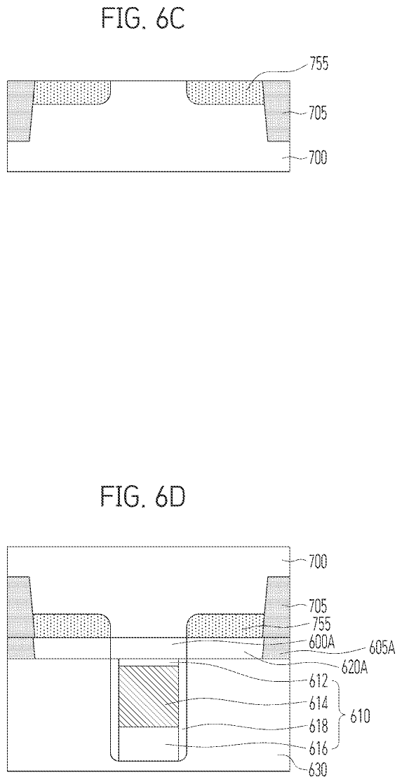

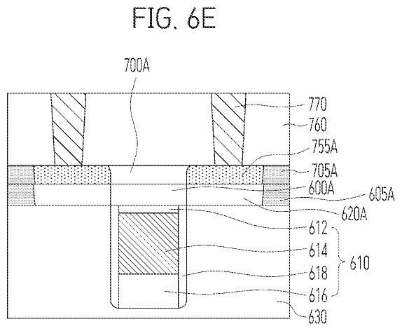

FIGS. 6A to 6E are cross-sectional views illustrating a semiconductor device and a method for fabricating the same, according to another embodiment of the present disclosure.

Referring to FIG. 6A, substantially the same processes as those described in FIGS. 1A to 1C may be performed to form a structure that includes a first semiconductor pattern 600A, an impurity region 620A, a first isolation pattern 605A, a gate structure 610 including a gate insulating layer 612, a gate electrode 614, a gate hard mask 616, a gate spacer 618, and a first interlayer insulating layer 630.

Referring to FIG. 6B, a second semiconductor substrate 700 may be provided. Also, a second isolation layer 705 may be formed to define an active region in the second semiconductor substrate 700. The second isolation layer 705 may be used to overlap with and contact the first isolation pattern 605A when bonding the second semiconductor substrate 700 and the structure of FIG. 6A. The second isolation layer 705 may be formed at a position overlapping with the first isolation pattern 605A.

Subsequently, a sacrificial insulating pattern 725 may be formed over the second semiconductor substrate 700 to cover an area overlapping the first semiconductor pattern 600A when bonding the second semiconductor substrate 700 and the structure of FIG. 6A.

Subsequently, a metal layer 750 may be formed over the sacrificial insulating pattern 725, the semiconductor substrate 700, and the second isolation layer 705 over their surface profiles.

Referring to FIG. 6C, a heat treatment process may be performed on the process result of FIG. 6B to react the metal of the metal layer 750 with the silicon of the semiconductor substrate 700 to form a metal silicide layer 755. The metal silicide layer 755 may be formed in the second semiconductor substrate 700, and may have an upper surface forming a flat surface with the upper surface of the second semiconductor substrate 700 and a lower surface located higher than the lower surface of the second isolation layer 705.

Subsequently, the unreacted portion of the metal layer 750 and the sacrificial insulating pattern 725 may be removed.

Referring to FIG. 6D, the process result of FIG. 6C may be flipped upside down and bonded to the structure of FIG. 6A. In this case, the second isolation layer 705 may overlap and contact the first isolation pattern 605A, the metal silicide layer 755 may overlap and contact the impurity region 620A, and the remainder of the second semiconductor substrate 700, except for the metal silicide layer 755, may overlap and contact the first semiconductor pattern 600A.

Referring to FIG. 6E, a planarization process, such as CMP, may be performed to remove a portion from the upper surface of the second semiconductor substrate 700 and to expose the metal silicide layer 755. Accordingly, a portion of the metal silicide layer 755 and a portion of the second isolation layer 705 may be removed.

The planarized second semiconductor substrate 700 will hereinafter be referred to as a second semiconductor pattern 700A, the planarized metal silicide layer 755 will hereinafter be referred to as a metal silicide pattern 755A, and the planarized second isolation layer 705 will hereinafter be referred to as a second isolation pattern 705A. The second semiconductor pattern 700A, the metal silicide pattern 755A, and the second isolation pattern 705A may be positioned at the same level as each other in the vertical direction, and may have flat upper surfaces and flat lower surfaces.

Since the first isolation pattern 605A and the second isolation pattern 705A are formed through separate processes, they may overlap each other, and may have sidewalls that are not aligned with each other. The metal silicide pattern 755A and the impurity region 620A may overlap each other, and may have sidewalls that are not aligned with each other. The first semiconductor pattern 600A and the second semiconductor pattern 700A may overlap each other, and may have sidewalls that are not aligned with each other. However, the embodiments of the present disclosure are not limited to this, and at least a portion of the sidewalls may be aligned with each other.

Subsequently, a second interlayer insulating layer 760 may be formed over the second semiconductor pattern 700A, the metal silicide pattern 755A, and the second isolation pattern 705A. A contact plug 770 may be formed to penetrate the second interlayer insulating layer 760 to be connected to the silicide pattern 755A.

According to the present embodiment, the metal silicide layer 755 may be formed separately from other components of the semiconductor device, so the quality of the metal silicide layer 755 may be improved.

According to the above embodiments of the present disclosure, it may be possible to improve the performance of the transistor and improve the fabricating processes.

Although various embodiments of the present disclosure have been described for illustrative purposes, it will be apparent to those skilled in the art that various changes and modifications may be made without departing from the spirit and scope of the present teachings as defined in the following claims. Furthermore, the embodiments may be combined to form additional embodiments.

What is claimed is:

1. A semiconductor device comprising:
a semiconductor pattern;
an impurity region disposed at a side of the semiconductor pattern and having a lower surface that forms a flat surface with a lower surface of the semiconductor pattern;
a gate structure disposed under the semiconductor pattern; and
a contact plug disposed over the impurity region and electrically connected to the impurity region.

2. The semiconductor device according to claim 1, further comprising:
an insulating layer disposed under the impurity region and covering the impurity region.

3. The semiconductor device according to claim 1, wherein the impurity region has an upper surface that forms a flat surface with an upper surface of the semiconductor pattern.

4. The semiconductor device according to claim 1, further comprising:
a metal silicide layer disposed between the impurity region and the contact plug.

5. The semiconductor device according to claim 4, wherein a sidewall of the metal silicide layer is aligned with a sidewall of the impurity region, and
an upper surface of the metal silicide layer forms a flat surface with an upper surface of the semiconductor pattern.

6. The semiconductor device according to claim 1, further comprising:
an isolation pattern disposed at a side of the impurity region and having a lower surface that forms a flat surface with the lower surface of the semiconductor pattern and an upper surface that forms a flat surface with an upper surface of the semiconductor pattern.

7. The semiconductor device according to claim 1, further comprising:
a first conductive line disposed under the gate structure and electrically connected to a gate electrode of the gate structure; and
a second conductive line disposed over the contact plug and electrically connected to the contact plug.

8. The semiconductor device according to claim 1, wherein the gate structure includes a gate electrode and a gate insulating layer interposed between the gate electrode and the semiconductor pattern.

9. The semiconductor device according to claim 1, wherein the gate structure includes a gate electrode, and a gate insulating layer that is interposed between the gate electrode and the semiconductor pattern and covers a sidewall of the gate electrode.

10. The semiconductor device according to claim 1, further comprising:
an additional semiconductor pattern disposed over the semiconductor pattern and contacting the semiconductor pattern; and
a metal silicide pattern disposed at a side of the additional semiconductor pattern and contacting the impurity region,
wherein the contact plug is disposed over the metal silicide pattern and is connected to the impurity region through the metal silicide pattern.

11. The semiconductor device according to claim 10, wherein the impurity region has an upper surface that forms a flat surface with an upper surface of the semiconductor pattern, and
the metal silicide pattern has a lower surface that forms a flat surface with a lower surface of the additional semiconductor pattern and an upper surface that forms a flat surface with an upper surface of the additional semiconductor pattern.

12. The semiconductor device according to claim 10, further comprising:
an isolation pattern disposed at a side of the impurity region and having a lower surface that forms a flat surface with the lower surface of the semiconductor pattern and an upper surface that forms a flat surface with an upper surface of the semiconductor pattern; and
an additional isolation pattern disposed at a side of the metal silicide pattern and having a lower surface that forms a flat surface with a lower surface of the additional semiconductor pattern and an upper surface that forms a flat surface with an upper surface of the additional semiconductor pattern.

13. A method for fabricating a semiconductor device, the method comprising:
forming a gate structure or sacrificial gate pattern on a semiconductor substrate;
forming an impurity region by doping impurities into the semiconductor substrate exposed by the gate structure or the sacrificial gate pattern;
after flipping the semiconductor substrate in which the impurity region is formed upside down, performing a planarization process to expose the impurity region; and
forming a contact plug over the planarized impurity region.

14. The method according to claim 13, further comprising:
transforming a portion of the planarized impurity region into a metal silicide layer, after performing the planarization process and before forming the contact plug.

15. The method according to claim 14, wherein the contact plug is disposed over the metal silicide layer and is connected to the planarized impurity region through the metal silicide layer.

16. The method according to claim 13, further comprising:
removing the sacrificial gate pattern when the sacrificial gate pattern is formed over the semiconductor substrate; and
forming the gate structure.

17. The method according to claim 16, wherein forming the gate structure is performed after forming the impurity region.

18. The method according to claim 16, further comprising:
transforming a portion of the planarized impurity region into a metal silicide layer, after the planarization process and before forming the contact plug, wherein forming the gate structure is performed after forming the metal silicide layer and after forming the contact plug.

19. The method according to claim 13, further comprising:
providing an additional semiconductor substrate;
forming a metal silicide layer in the additional semiconductor substrate;
after flipping the additional semiconductor substrate in which the metal silicide layer is formed upside down, bonding the additional semiconductor substrate in which the metal silicide layer is formed over a flat surface formed by the planarization process.

20. The method according to claim 19, wherein, during the bonding, the metal silicide layer contacts the impurity region.

21. The method according to claim 19, further comprising:
performing an additional planarization process to expose the metal silicide layer, after the bonding.

22. A semiconductor device comprising:
a semiconductor pattern;
an impurity region disposed at a side of the semiconductor pattern, the impurity region having a bottom surface that forms a flat surface with a bottom surface of the semiconductor pattern;
a gate structure disposed under the semiconductor pattern, the gate structure fully overlapping with the semiconductor pattern in a lateral direction;
a contact plug disposed over the impurity region, the contact plug being electrically connected to the impurity region; and
an insulating layer disposed under the impurity region and covering the impurity region.
